(19) United States
(12) Patent Application Publication
(10) Pub. No.: US 2025/0311572 A1
(43) Pub. Date: Oct. 2, 2025

(54) DISPLAY DEVICE

(71) Applicant: LG DISPLAY CO., LTD., Seoul (KR)

(72) Inventors: Won Hoon PARK, Paju-si (KR); Choong Gi AN, Paju-si (KR); Seo In LEE, Paju-si (KR); Dhang KWON, Paju-si (KR); Hang Sup CHO, Paju-si (KR)

(73) Assignee: LG DISPLAY CO., LTD., Seoul (KR)

(21) Appl. No.: 19/088,903

(22) Filed: Mar. 24, 2025

(30) Foreign Application Priority Data
Mar. 26, 2024 (KR) 10-2024-0041280
Oct. 25, 2024 (KR) 10-2024-0147765

(51) Int. Cl. H10K 59/131; H10K 59/121

(52) U.S. Cl. CPC H10K 59/131; H10K 59/1213

(57) ABSTRACT

The embodiment discloses a display device including: a first display area including a plurality of first pixels; and a second display area including a plurality of pixel areas where a plurality of second pixels are arranged and a plurality of light transmitting areas arranged between the plurality of pixel areas. The second display area includes a plurality of metal wires arranged in the pixel areas and a plurality of light transmitting wires arranged in the light transmitting areas and connected to the plurality of metal wires arranged in the pixel areas respectively.

### CROSS-REFERENCE TO RELATED APPLICATION(S)

This application claims priority to and the benefit of Korean Patent Applications No. 10-2024-0041280, filed Mar. 26, 2024, and No. 10-2024-0147765, filed Oct. 25, 2024, in the Republic of Korea, the entire disclosure of each of which is incorporated herein by reference for all purposes.

### 1. TECHNICAL FIELD

The present disclosure relates to a display device.

### 2. DISCUSSION OF THE RELATED ART

An electroluminescence display device may be divided into an inorganic light-emitting display device and an organic light-emitting display device according to the material of the emission layer. An active matrix type organic light-emitting display device includes an organic light-emitting diode (hereinafter, referred to as “OLED”) that emits light by itself, and has the advantage of fast response speed, high light-emitting efficiency, high luminance and wide viewing angle. The organic light-emitting display device has OLEDs (Organic Light Emitting Diodes) formed in each pixel. The organic light-emitting display device has a fast response speed, excellent light-emitting efficiency, luminance, and wide viewing angle, and also has excellent contrast ratio and color reproducibility because black gray scale can be expressed as complete black.

Recently, the multimedia function of mobile terminals has been improved. For example, a camera is built into mobile terminals as standard, and the resolution of the camera is increasing to the level of existing digital cameras. However, the front camera of the mobile terminal limits the screen design, making the screen design difficult. In order to reduce the space occupied by the camera, a screen design including a notch or a punch hole has been adopted in mobile terminals, but the screen size is still limited due to the camera, making it difficult to implement a full-screen display.

The description provided in the background section should not be assumed to be prior art merely because it is mentioned in or associated with the background section. The background section may include information that describes one or more aspects of the subject technology.

### SUMMARY

In order to implement a full-screen display, a method of providing a sensing area in which pixels are arranged inside the display panel screen and arranging a camera and/or various sensors in the sensing area is being proposed. Such structure of the display device may be referred to as an Under Display Camera (UDC) structure. However, the inventors of the present disclosure recognized that the light transmittance performance of the sensing area in the UDC structure may be low due to the pixels arranged over the camera or various other sensors. Accordingly, the inventors of the present disclosure have conducted various experiments to implement a display device that can improve the light transmittance performance of the sensing area where the sensor is disposed.

Accordingly, embodiments of the present disclosure are directed to a display device that substantially obviates one or more of the problems due to limitations and disadvantages of the related art.

Additional features and aspects will be set forth in part in the description that follows, and in part will be apparent from the description, or may be learned by practice of the inventive concepts provided herein. Other features and aspects of the inventive concepts may be realized and attained by the structures pointed out in the present disclosure, or derivable therefrom, and the appended claims as well as the appended drawings.

To achieve these and other aspects of the inventive concepts, as embodied and broadly described herein, a display device comprises: a first display area including a plurality of first pixels; and a second display area including a plurality of pixel areas where a plurality of second pixels are arranged and a plurality of light transmitting areas arranged between the plurality of pixel areas, wherein the second display area includes a plurality of metal wires arranged in the pixel areas and a plurality of light transmitting wires arranged in the light transmitting areas and connected to the plurality of metal wires respectively.

The metal wires in the pixel areas of the second display area are spaced apart with the light transmitting areas interposed therebetween, and the light transmitting wires extend into the pixel areas to connect the adjacent metal wires.

The plurality of light transmitting wires may form a wire group with two or more light transmitting wires, and the plurality of wire groups are spaced apart from each other.

The light transmitting wires in the wire group may include a first end and a second end, and the interval between the light transmitting wires becomes wider towards the first end.

A first interval between the light transmitting wires at the first end may be wider than a second interval between the metal wires corresponding to the light transmitting wires, and the second interval may be wider than a third interval between the light transmitting wires at the second end.

The second display area may include a first connection portion where one end of a metal wire is electrically connected to a corresponding light transmitting wire, and a second connection portion where the other end of the metal wire is electrically connected to the corresponding light transmitting wire, and both the first connection portion and the second connection portion may be disposed within the plurality of pixel areas.

Each of the plurality of first pixels and the plurality of second pixels may include a light-emitting element including an anode electrode, an emitting layer and a cathode electrode, and the cathode electrode may extend across the first display area and the second display area, and may include an opening hole removed in a portion corresponding to the light transmitting area.

The portion of the cathode electrode corresponding to the light transmitting areas may be patterned to be floated and electrically connected to the light transmitting area.

The pixel area may include a first electrode connecting the end of the metal wire and the end of the light transmitting wire, and the first electrode may include a first contact connected to the semiconductor layers of the transistor and a third contact connected to the light transmitting wire.

The first contact and the third contact may be spaced apart from each other and do not overlap on the plane.

The metal wire may include a second contact connected to the first electrode.

The first contact and the second contact may overlap on the plane.

The width of the light transmitting wire may be wider than the width of the metal wire.

The light transmitting wire may be disposed in the same layer as the semiconductor layers of the transistor.

The second display area may include: a substrate; a first semiconductor layer disposed on the substrate; a first gate insulating layer disposed on the first semiconductor layer; a light transmitting wire disposed over the first gate insulating layer; an insulating layer disposed on the light transmitting wire; a first electrode disposed on the insulating layer; a first planarization layer disposed on the first electrode; and a metal wire disposed on the first planarization layer.

The display device may further include a second semiconductor layer disposed on the first gate insulating layer, and a second gate insulating layer disposed on the second semiconductor layer, and the light transmitting wire may be disposed over the second gate insulating layer.

The first electrode may include a first contact connected to the first semiconductor layer through the first gate insulating layer and the insulating layer, and a second contact connected to the light transmitting wire through the insulating layer.

The first contact and the second contact may be offset on the plane.

The metal wires may include a third contact connected to the first electrode through the first planarization layer.

The second display area may include a sensor.

The sensor may include an infrared sensor or a camera.

The resolution of the plurality of first pixels and the resolution of the plurality of second pixels may be the same.

The resolution of the plurality of first pixels and the resolution of the plurality of second pixels may be different.

The plurality of first pixels and second pixels each include a plurality of sub-pixels, and the size of the sub-pixels of the plurality of second pixels may be smaller than the size of the sub-pixels of the plurality of first pixels.

The plurality of light transmitting areas and the plurality of pixel areas may be alternately arranged in an extending direction of the metal wires or the light transmitting wires.

In another aspect, a display device comprises a first display area including a plurality of first pixels; and a second display area including a plurality of pixel areas where a plurality of second pixels are arranged and a plurality of light transmitting areas arranged between the plurality of pixel areas. A plurality of signal wires may extend within the second display area to pass through the plurality of pixel areas and the plurality of light transmitting areas, and each of the plurality of signal wires may include a metal wire disposed in the pixel areas and a light transmitting wire disposed in the light transmitting areas and electrically connected to the metal wire.

According to example embodiments of the present disclosure, the light transmittance in the sensing area can be increased to improve the performance of the infrared sensor or camera.

According to example embodiments of the present disclosure, the resistance of the wire in the sensing area may be reduced, enabling low-power operation.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles.

In the drawings:

FIG. 1 is a conceptual diagram of a display device according to an example embodiment of the disclosure;

FIG. 2 is a cross-sectional view showing a display panel according to an example embodiment of the disclosure;

FIG. 3 is a diagram showing the pixel arrangement of a first display area according to an example embodiment of the disclosure;

FIG. 4 is a diagram showing the pixels and the light transmitting areas of a second display area according to an example embodiment of the disclosure;

FIG. 5 is a diagram showing an example of a structure in which the wires of the second display area are composed of metal;

FIG. 6 is an example of an enlarged view of a part of FIG. 5;

FIG. 7 is an example of a cross-sectional view along the I-I′ direction of FIG. 6;

FIG. 8 is a diagram showing the wire structure of the second display area according to an example embodiment of the disclosure;

FIG. 9 is a diagram showing a schematic cross-sectional structure of the wire disposed in the light transmitting area according to an example embodiment of the disclosure;

FIG. 10 is a cross-sectional view of the second display area according to an example embodiment of the disclosure;

FIG. 11 is a modified embodiment of FIG. 10;

FIG. 12 is a diagram showing the sub-pixels and the wire structure of the first display area and the second display area according to an example embodiment of the disclosure;

FIG. 13 is an example of a partially enlarged view of the second connection portion of FIG. 12;

FIG. 14 is an example of an exploded view of the wire of FIG. 13;

FIG. 15 is an example of a cross-sectional view in the A-A′, B-B′, and C-C′ directions of FIG. 13;

FIG. 16 is an example of a partially enlarged view of the first connection portion;

FIG. 17 is an example of a cross-sectional view in the D-D′ direction of FIG. 16;

FIG. 18 is a result of measuring the transmittance of the display device according to an example embodiment of the disclosure; and.

FIG. 19 is a result of measuring the zero-order resonance (ZOR) characteristics of the display device according to an example embodiment of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

The advantages and features of the disclosure, and the methods of achieving them will become clear by referring to the example embodiments described in detail below with reference to the accompanying drawings. However, the disclosure is not limited to the example embodiments disclosed herein, but may be implemented in various other forms, and the example embodiments are provided to make the disclosure of the disclosure complete to assist those skilled in the art to fully understand the scope of the present disclosure, and the disclosure is defined only by the scope of the appended claims.

In the drawings provided to explain the embodiments of the disclosure, the shapes, sizes, ratios, angles, and numbers, which are illustrated in the drawings to describe various example embodiments of the present disclosure are merely given by way of example, and the disclosure is not limited to the disclosed matters. Throughout the specification, the same reference numerals refer to the same components. Also, in explaining the disclosure, if the detailed description of the related known technology is considered to unnecessarily obscure the gist of the disclosure, the detailed description is omitted. Any implementation described herein as an “example” is not necessarily to be construed as preferred or advantageous over other implementations.

When the terms “comprising”, “having”, and “consisting” are used in the specification, unless explicitly stated otherwise, other parts may be added. When a component is expressed in the singular, it includes the plural unless there is a specific description stating otherwise.

In interpreting the components, it is interpreted as including the error range or tolerance range even if there is no explicit description of such an error or tolerance range.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In the description of the embodiments, the “first”, “second”, “A,” “B,” “(a),” “(b),” etc. are used to describe various components, but these terms may be merely for differentiating one component from another component, and the essence, sequence, order, or number of the corresponding components should not be limited by these terms. Therefore, the first component described below may be the second component within the technical scope of the disclosure. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

The same reference numerals throughout the specification refer to the same components.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

The features of the various embodiments may be partially or completely coupled or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

A display device according to the present disclosure may be implemented as a light emitting display device or a quantum dot display (QDD) device. Hereinafter, for convenience of description, a light emitting display device self-emitting light based on an inorganic light emitting diode or an organic light emitting diode will be described for example, but the present disclosure is not limited thereto, and other various types of display device may also be similarly applied.

In the present disclosure, a pixel circuit and a gate driver formed on a display panel may include a plurality of transistors. The transistors may be implemented with oxide thin film transistors (oxide TFTs) including an oxide semiconductor, low temperature polysilicon (LTPS) TFTs including low temperature polysilicon, and the like.

Moreover, a thin film transistor (TFT) described below may be implemented with an n-type TFT, a p-type TFT, or a combination of an n-type TFT and a p-type TFT. A TFT may be a three-electrode element including a gate, a source, and a drain. The source may be an electrode which provides a carrier to a transistor. In the TFT, a carrier may start to flow from the source. The drain may be an electrode where the carrier flows from the TFT to the outside. For example, in the TFT, the carrier flows from the source to the drain.

In the p-type TFT, because a carrier is a hole, a source voltage may be higher than a drain voltage so that the hole flows from the source to the drain. In the p-type TFT, because the hole flows from the source to the drain, a current may flow from the source to the drain. On the other hand, in the n-type TFT, because a carrier is an electron, a source voltage may be lower than a drain voltage so that the electron flows from the source to the drain. In the n-type TFT, because the electron flows from the source to the drain, a current may flow from the drain to the source. However, a source and a drain of a TFT may switch therebetween based on a voltage applied thereto. Based thereon, in the following description, one of a source and a drain will be described as a first electrode, and the other of the source and the drain will be described as a second electrode. However, since the source electrode and the drain electrode can be changed according to an applied voltage, the source electrode and the drain electrode of the transistor are not fixed.

Hereinafter, various embodiments of the disclosure will be described in detail with reference to the accompanying drawings. Further, all the components of each display device according to all embodiments of the present disclosure are operatively coupled and configured.

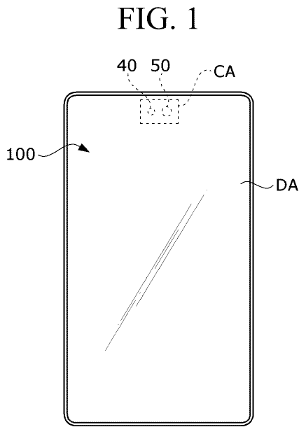

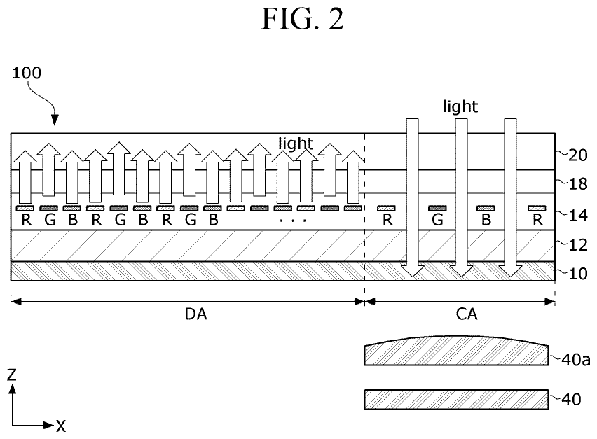

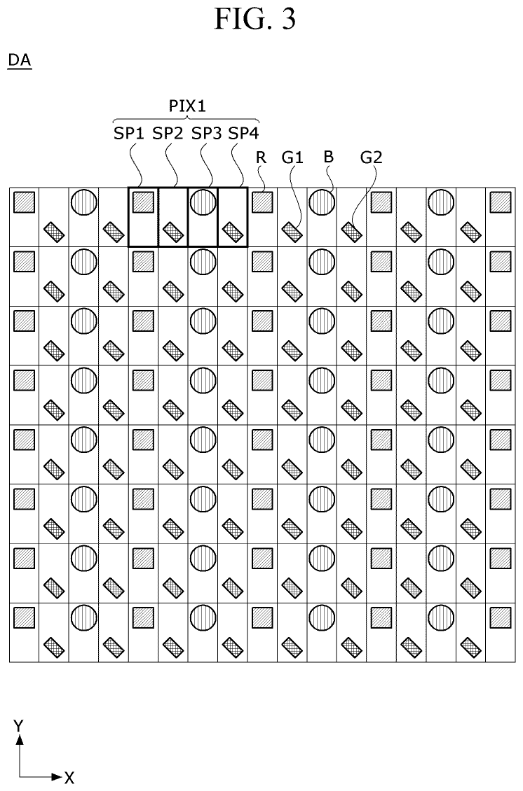

FIG. 1 is a conceptual diagram of a display device according to an embodiment of the disclosure. FIG. 2 is a schematic cross-sectional view of a display panel according to an embodiment of the disclosure. FIG. 3 is a diagram showing the pixel arrangement of a first display area according to an embodiment of the disclosure.

Referring to FIG. 1, the display device may have the entire front surface of the display panel 100 as the display area. Therefore, a full-screen display may be possible.

The display area may include a first display area DA and a second display area CA. The first display area DA and the second display area CA both output images, but the resolution may be different. For example, the resolution of the plurality of second pixels arranged in the second display area CA may be lower than the resolution (or density) of the plurality of first pixels arranged in the first display area DA. As the resolution (or density) of the plurality of second pixels arranged in the second display area CA decreases, relatively more light may be transmitted into the sensors 40, 50 arranged in the second display area CA.

However, the embodiments of the disclosure are not limited thereto. For example, if the second display area CA has sufficient light transmittance or an appropriate compensation algorithm is implemented, the resolution of the first display area DA and the second display area CA may be the same. For example, the pixels of the second display area CA may be configured smaller than the pixels of the first display area DA to adjust the resolution.

The second display area CA may be an area where the sensors 40, 50 are disposed. The second display area CA overlaps with various sensors, so the area thereof may be smaller than that of the first display area DA that outputs the majority of the image. The second display area CA may be an area where various sensors collect information. The second display area CA is illustrated as being disposed at the top of the display device, but the position and size of the second display area CA may be variously modified.

The sensors 40, 50 may include at least one of an image sensor, a proximity sensor, an illuminance sensor, a gesture sensor, a motion sensor, a fingerprint recognition sensor, and a biometric sensor. For example, the first sensor 40 may be an infrared sensor, and the second sensor 50 may be an imaging or video capture unit, but are not limited thereto. The first sensor 40 may include an infrared emitting element that emits infrared light to the outside and a light receiving element that receives the infrared light reflected from the user's face. The display device may generate a 3D feature map using the light data received by the light receiving element.

Referring to FIGS. 2 and 3, the first display area DA and the second display area CA may include a pixel array in which the pixels are arranged, and pixel data may be written to the pixels to display an image. The number of pixels per unit area (Pixels per Inch: hereinafter referred to as “PPI”) of the second display area CA may be lower than that that of the first display area DA to secure the light transmittance of the second display area CA, but the present disclosure is not limited thereto.

The pixel array of the first display area DA may include a pixel area with a high PPI. The pixel array of the second display area CA may include a pixel area with a relatively low PPI separated by the light transmitting areas. In the second display area CA, external light passes through the light transmitting area with high light transmittance and is incident on the sensor under the display panel 100.

Since both the first display area DA and the second display area CA include pixels, the input image may be implemented on the first display area DA and the second display area CA. Therefore, a full-screen display may be possible.

The pixels of the first display area DA and the second display area CA may each include sub-pixels of different colors to implement the color of the image. The sub-pixels may include red, green and blue sub-pixels. Although not shown, the pixel may further include a white sub-pixel. Each of the sub-pixels may include a pixel circuit unit and red, green and blue light-emitting elements (such as OLED). Hereinafter, a “pixel” may be interpreted as a “sub-pixel.”

The second display area CA may include pixels, a lens 40a disposed under the screen of the display panel 100, and the first sensor 40. The lens 40a may refract or diffract the light received by the sensor. The lens 40a may be omitted depending on the type of sensor. The pixels of the second display area CA may have pixel data written in the display mode to display the input image.

The pixels may be disposed as real color pixels or pentile pixels. In the pentile pixel, two sub-pixels of different colors are driven as one pixel using a predetermined pixel rendering algorithm to realize a resolution higher than a resolution of the real-color pixel. The pixel rendering algorithm may compensate for insufficient color representation of each pixel using colors of light emitted from adjacent pixels.

The first sensor 40 may irradiate infrared light and use the reflected light to generate a 3D feature map. The first sensor 40 may be an infrared camera, but is not limited thereto and may be various image acquisition devices that can acquire images.

To secure the light transmittance, a compensation algorithm for compensating the luminance and color coordinates of the pixels in the second display area CA may be applied due to the removal of pixels in the second display area CA.

The display panel 100 may have a width in the X-axis direction, a length in the Y-axis direction, and a thickness in the Z-axis direction. The display panel 100 may include a circuit layer 12 disposed on the substrate 10, and a light-emitting element layer 14 disposed on the circuit layer 12. A polarizer 18 may be disposed on the light-emitting element layer 14, and a cover glass 20 may be disposed on the polarizer 18.

The circuit layer 12 may include pixel circuits connected to data lines, gate lines, power lines, and a gate driver connected to the gate lines.

The circuit layer 12 may include transistors implemented as TFTs (Thin Film Transistors) and capacitors as circuit components. The wires and circuit components in the circuit layer 12 may be implemented with multiple insulating layers, two or more separated metal layers with the insulating layers interposed therebetween, and semiconductor layers including semiconductor material.

The light-emitting element layer 14 may include light-emitting elements driven by the pixel circuits. The light-emitting element may be implemented as an OLED. The OLED may include an organic compound layer formed between an anode and a cathode. However, the embodiments of the disclosure are not limited thereto. For example, the light-emitting element layer may include micro light-emitting elements.

The light-emitting element layer 14 may be disposed on the pixels that selectively transmit red, green, and blue wavelengths, and may further include a color filter array.

The light-emitting element layer 14 may be covered by a protective film, and the protective film may be covered by an encapsulation layer. The protective film and the encapsulation layer may have a structure in which organic films and inorganic films are alternately stacked. The inorganic film can block the penetration of moisture and oxygen. The organic film may planarize the surface of the inorganic film. When the organic film and the inorganic film are stacked in multiple layers, the path of moisture or oxygen movement is longer than that of a single layer, so that the penetration of moisture and oxygen affecting the light-emitting element layer 14 may be effectively blocked or reduced.

A polarizer 18 may be disposed on the encapsulation layer. The polarizer 18 may improve the outdoor visibility of the display device. The polarizer 18 may reduce the light reflected from the surface of the display panel 100 and block the light reflected from the metal of the circuit layer 12, thereby improving the brightness of the pixels. The polarizer 18 may be implemented as a polarizer in which a linear polarizer and a phase retardation film are bonded, or a circular polarizer.

Referring to FIG. 3, the first display area DA may include a plurality of first pixels (PIX1) arranged in a matrix. The plurality of first pixels (PIX1) may include R, G1, G2, and B sub-pixels. For example, the first unit pixel may be composed of R and G1 sub-pixels SP1, SP2, and the second unit pixel may be composed of B and G2 sub-pixels SP3, SP4. However, this is not limited thereto, and the plurality of first pixels PIX1 may also be real type pixels including RGB sub-pixels.

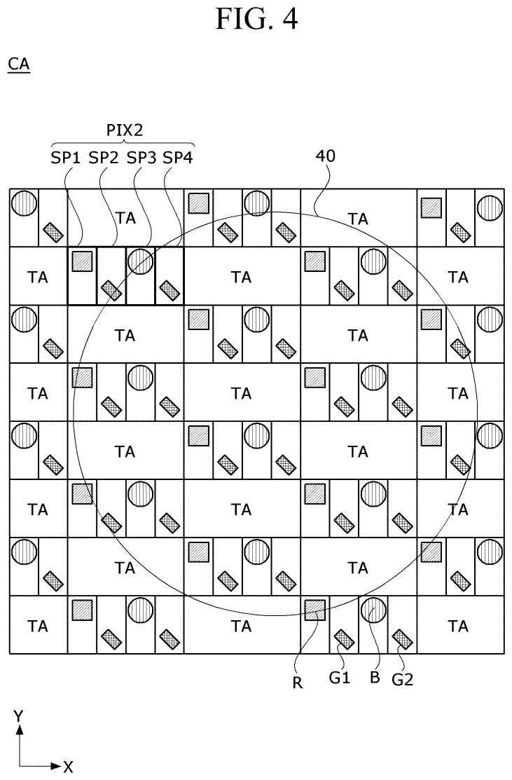

FIG. 4 is a diagram showing the pixels and the light transmitting areas of the second display area according to an embodiment of the disclosure.

Referring to FIG. 4, the second display area CA may include a plurality of second pixels PIX2 and a plurality of light transmitting areas TA. The plurality of light transmitting areas TA may be disposed between the plurality of second pixels PIX2. Specifically, the light transmitting areas TA may be alternately arranged in the first direction (X-axis direction) and the second direction (Y-axis direction) with the second pixels PIX2. Although it is shown in FIG. 4 that one second pixel PIX2 is disposed between two light transmitting areas TA adjacent to each other in the first or second direction, it is only described for ease of illustration, and the present disclosure is not limited thereto, for example, two or more second pixels PIX2 may be disposed between the adjacent two transmitting areas TA. External light may be received by the first sensor 40 through the light transmitting areas TA. As the area of the light transmitting areas TA increases, the resolution of the second display area CA may be lower than the resolution of the first display area DA.

The light transmitting area TA may include transparent media with high light transmittance without metal so that light may be incident with minimal light loss. The light transmitting area TA may be composed of transparent insulating materials without including metal wires or pixels as much as possible. The light transmittance of the second display area CA may be higher as the area of the light transmitting area TA increases.

The plurality of second pixels PIX2 may include one or two unit pixels. For example, the first unit pixel of the second pixel PIX2 may be composed of R and G1 sub-pixels SP1, SP2, and the second unit pixel may be composed of B and G2 sub-pixels SP3, SP4. The shape and arrangement of the second pixels PIX2 may be the same as or different from the first pixels PIX1.

The shape of the light transmitting area TA is illustrated as a rectangle, but is not limited thereto. For example, the light transmitting area TA may be designed in various shapes such as a circle, an ellipse, or a polygon. For example, the light transmitting area TA may have a line shape.

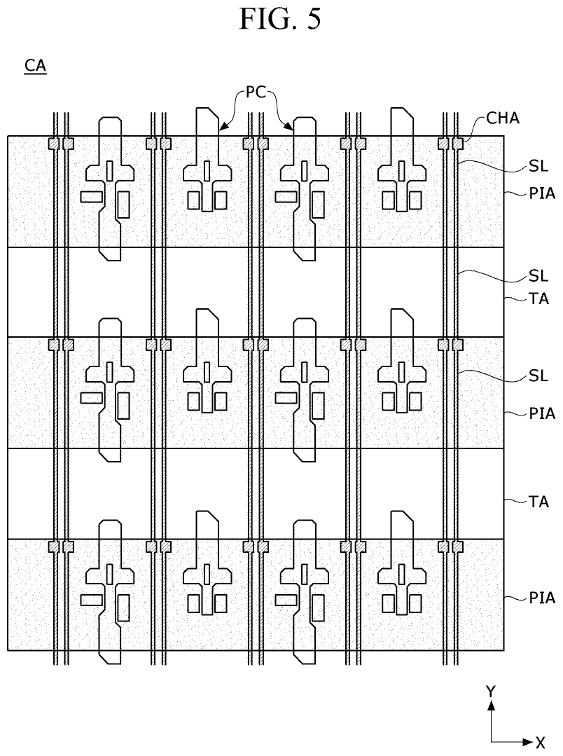

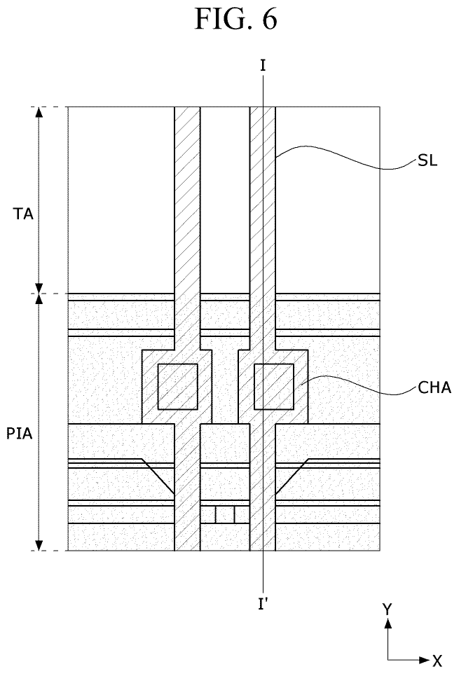

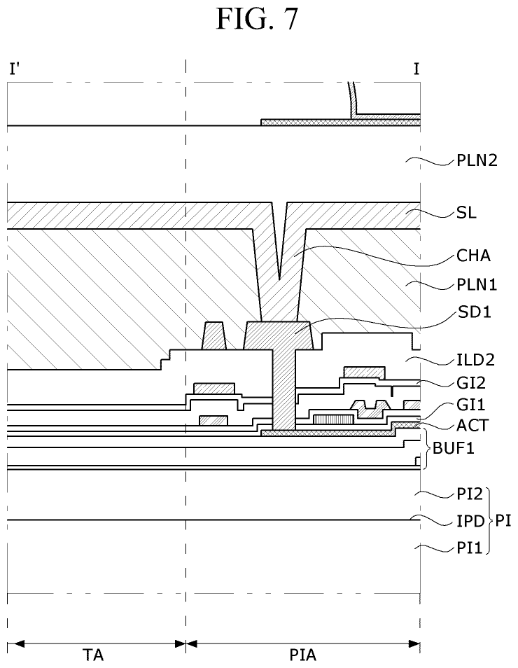

FIG. 5 is a diagram showing a structure in which the wires of the second display area are composed of metal. FIG. 6 is an enlarged view of a part of FIG. 5. FIG. 7 is a cross-sectional view of FIG. 6.

Referring to FIGS. 5 to 7, in the second display area CA, the pixel area (PIA) and the light transmitting area TA may be arranged in the form of multiple lines extending in the first direction (X-axis direction). Light transmitting areas TA may be disposed between the multiple pixel areas PIA. For example, the light transmitting areas TA and the pixel areas PIA may be alternately arranged in the second direction. Alternatively, the light transmitting areas TA and the pixel areas PIA may also be alternately arranged in the first direction.

The multiple wires SL may extend in the second direction (Y-axis direction) to apply voltage to each sub-pixel. A wire SL may be a data line connected to the anode electrode, but the embodiments are not limited thereto.

The wire SL may apply voltage to the sub-pixels disposed in the second direction across the light transmitting area TA in each pixel area PIA. If the wire SL is made of a metal material, it may block the light incident on the light transmitting area TA, reducing the efficiency and performance of the infrared camera or RGB camera. The wire SL may be composed of Ti/Al/Ti, but the embodiments of the disclosure are not limited thereto. For example, the wire SL may also be made of a light transmitting material such as ITO.

The wire SL may extend in the second direction while being connected to the semiconductor layers of the transistor arranged in each sub-pixel. The wire SL may be electrically connected to the first electrode SD1 through a contact portion CHA penetrating the first planarization layer PLN1. The first electrode SD1 may be electrically connected to the first semiconductor layer (ACT) of the transistor.

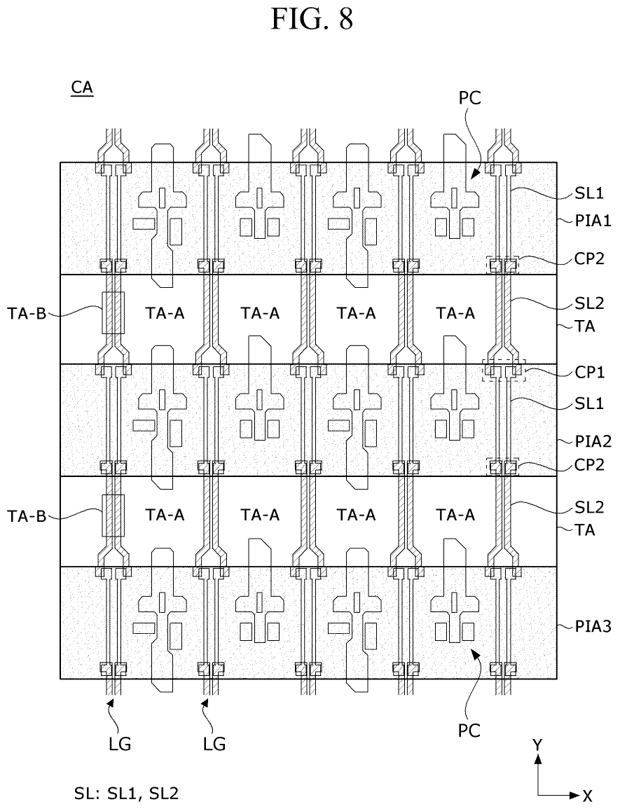

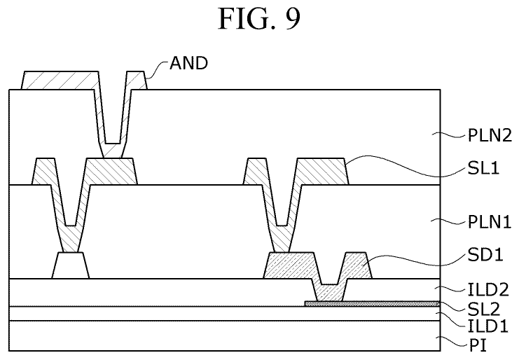

FIG. 8 is a diagram showing the wire structure of the second display area according to an embodiment of the disclosure. FIG. 9 is a diagram showing a schematic cross-sectional structure of the wire disposed in the light transmitting area according to an embodiment of the disclosure.

Referring to FIG. 8, the second display area CA according to the embodiment may have the multiple light transmitting areas TA and the multiple pixel areas PIA alternately arranged. The pixel areas PIA may be areas where pixel circuits PC are formed and a plurality of second pixels are arranged. The pixel areas PIA may be continuously arranged in the first direction (X-axis direction) to form pixel lines, and the light transmitting areas TA may be continuously arranged in the first direction (X-axis direction) to form light transmitting lines. The plurality of light transmitting areas TA may be disposed between the multiple pixel areas PIA in the second direction (Y-axis direction).

The second display area CA may have multiple signal wires SL extending in the second direction (Y-axis direction) to pass through the pixel areas PIA and the light transmitting areas TA. The multiple signal wires SL may be spaced apart in the first direction and each extend in the second direction.

The signal wires SL may include a plurality of metal wires SL1 disposed in the pixel areas PIA and a plurality of light transmitting wires SL2 disposed in the light transmitting areas TA. According to the embodiment, the metal wire SL1 and the light transmitting wire SL2 are electrically connected to form one signal wire SL, so that voltage can be applied to the multiple sub-pixels arranged in the second direction.

The metal wires SL1 in the multiple pixel areas PIA may be spaced apart with the light transmitting areas TA interposed therebetween. For example, the light transmitting area TA may be disposed between the first pixel area (PIA1) and the second pixel area (PIA2) spaced apart in the second direction, and between the second pixel area (PIA2) and the third pixel area (PIA3) spaced apart in the second direction.

The signal wire SL may include a first connection portion CP1 where one end of the metal wire SL1 is electrically connected to the light transmitting wire SL2, and a second connection portion CP2 where the other end of the metal wire SL1 is electrically connected to the light transmitting wire SL2.

The first connection portion CP1 and the second connection portion CP2 may be disposed inside the pixel area PIA. If the first connection portion CP1 and the second connection portion CP2 are disposed outside the pixel area PIA, the metal wire SL1 may extend into the light transmitting area TA, reducing the area of the light transmitting area TA. According to the embodiment, the two connection portions CP1, CP2 may be disposed inside the pixel area PIA of the second display area CA.

According to the embodiment, the metal wire SL1 may be electrically connected to different light transmitting wires SL2 at its one end and the other end. The light transmitting wire SL2 may also be electrically connected to different metal wires SL1 at its one end and the other end. In the second display area CA, the multiple light transmitting wires SL2 and metal wires SL1 may be alternately arranged in the second direction.

The metal wire SL1 disposed in the first pixel area (PIA1) and the metal wire SL1 disposed in the second pixel area (PIA2) may be electrically connected by the light transmitting wire SL2 disposed in the light transmitting area TA.

The light transmitting wire SL2 may include a light transmitting material with high light transmittance that may minimize or reduce the reflection of the incident light. The light transmitting wire SL2 may include transparent oxide semiconductors such as ITO (Indium Tin Oxide), IGZO (Indium Gallium Zinc Oxide), IZO (Indium Zinc Oxide), ZnO, ZTO, GZO, and ZITO, but the present disclosure is not limited thereto. According to the embodiments of this specification, the light transmitting wire SL2 may utilize various light transmitting materials that may transmit visible light or infrared light.

Two or more of the multiple signal wires SL may form a wire group LG. The multiple wire groups LG may be spaced apart. A pair of signal wires SL forming one wire group LG may be disposed adjacent to each other. However, the embodiments of the disclosure are not limited thereto. For example, the multiple light transmitting wires SL2 may not form a wire group and may be disposed at the same interval without grouping. Alternatively, three or more signal wires may form a wire group LG.

The light transmitting area TA may be divided into multiple first light transmitting areas TA-A and multiple second light transmitting areas TA-B by the multiple wire groups LG.

The multiple first light transmitting areas TA-A may be areas disposed between the wire groups LG, which may be relatively high in light transmittance. The first light transmitting area TA-A may have high light transmittance because it does not include metal material.

The multiple second light transmitting areas TA-B may be areas where the wire groups LG are disposed. The light transmitting wire SL2 disposed in the second light transmitting area TA-B has higher light transmittance than the metal wire SL1. Therefore, light can pass through the second light transmitting area TA-B to improve the sensor performance.

The pixel area PIA of the second display area CA may have a lower pixel density than the first display area DA. Therefore, the pixel area PIA of the second display area CA may have higher transmittance than the pixel area of the first display area DA. However, the embodiments of the disclosure are not limited thereto. For example, the pixel area PIA of the first display area DA and the pixel area PIA of the second display area CA may have the same resolution, and the light transmittance may be the same.

The light transmittance of the second light transmitting area TA-B may be higher than the pixel area PIA of the second display area CA. The light transmittance of the second light transmitting area TA-B may be lower than the first light transmitting area TA-A without wires. The area of the first light transmitting area TA-A may be wider than the second light transmitting area TA-B.

Referring to FIG. 9, multiple insulating layers ILD1, ILD2 may be disposed on the substrate PI, and the light transmitting wire SL2 may be disposed between the multiple insulating layers ILD1, ILD2. In the embodiment, the light transmitting wire SL2 is shown as being disposed between two insulating layers ILD1, ILD2, but the embodiments of the disclosure are not limited thereto. For example, the multiple insulating layers ILD1, ILD2 may be composed of 4 or 6 layers.

The first electrode SD1 may be disposed on the light transmitting wire SL2, and the metal wire SL1 may be disposed on the first electrode SD1. The first electrode SD1 may be electrically connected to the light transmitting wire SL2 through a contact portion, and the metal wire SL1 may be electrically connected to the first electrode SD1 through a contact portion. However, the embodiments of the disclosure are not limited thereto. For example, the first electrode SD1 may be omitted and the metal wire SL1 may be directly connected to the light transmitting wire SL2 by penetrating multiple insulating layers.

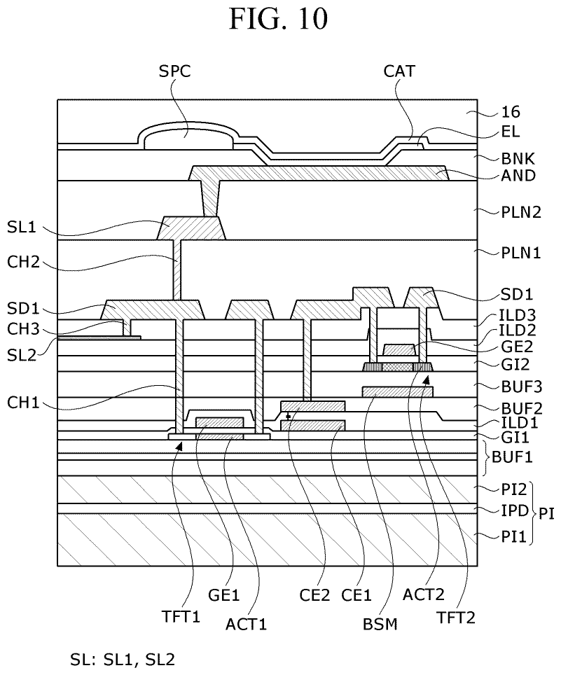

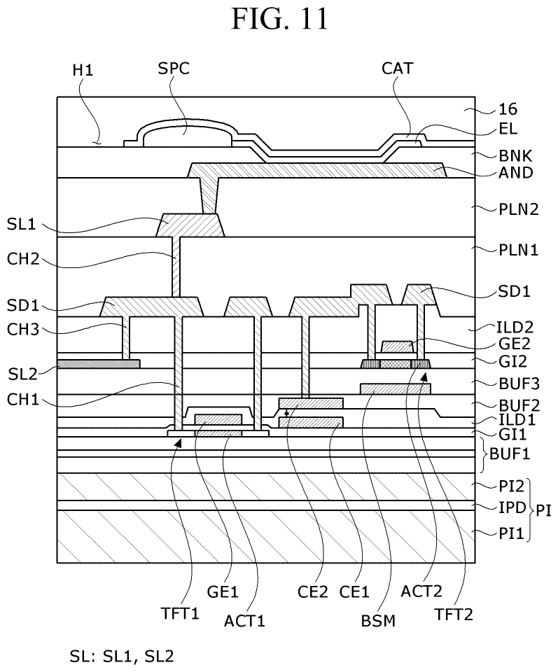

FIG. 10 is a cross-sectional view of the second display area according to an embodiment of the disclosure. FIG. 11 is a modified embodiment of FIG. 10.

Referring to FIG. 10, the substrate PI may include a first substrate PI1 and a second substrate PI2. And, an inorganic film IPD may be disposed between the first substrate PI1 and the second substrate PI2. The inorganic film IPD may block the penetration of moisture. The substrate PI may be formed of polyimide, so it may be referred to as a PI substrate, and the first and second substrates PI1, PI2 may be referred to as the first and second PI substrates, respectively. However, the present disclosure is not limited thereto. For example, the first substrate PI1 and the second substrate PI2 may be formed of same or different materials. In addition, each of the first substrate PI1 and the second substrate PI2 may include a plastic substrate, a glass substrate, or a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate (PEN), polyether sulfone(PES), cyclic olefin copolymer(COC), triacetylcellulose (TAC) film, polyvinyl alcohol (PVA) film, polyimide(PI) film, and polystyrene(PS), which is only an example and is not necessarily limited thereto.

A first buffer layer BUF1 may be formed on the second substrate PI2. The first buffer layer BUF1 may be formed as a multi-layer insulating film of oxide film (SiO2) and nitride film (SINx). A first semiconductor layer ACT1 is formed on the first buffer layer (BUF1). The first semiconductor layer ACT1 may include a patterned polysilicon semiconductor layer in a photolithography process. The first semiconductor layer ACT1 may include an active pattern of polysilicon that forms a semiconductor channel in the first TFT TFT1.

A first gate insulating layer GI1 may be deposited on the first buffer layer BUF1 to cover the first semiconductor layer ACT1. The first gate insulating layer GI1 may include an inorganic insulating material layer. A first metal layer may be disposed on the first gate insulating layer GI1. The first metal layer may be insulated from the first semiconductor layer by the first gate insulating layer GI1.

The first metal layer may include single-layer metal patterns or multilayer metal patterns patterned in a photolithography process. The first metal layer may include the gate electrode GE1 of the first TFT TFT1 and the capacitor electrode CE1.

The first interlayer insulating layer ILD1 may be formed on the first gate insulating layer GI1 to cover the patterns of the first metal layer. The first interlayer insulating layer ILD1 may include an inorganic insulating material. A second buffer layer BUF2 and a third buffer layer BUF3 may be formed on the first interlayer insulating layer ILD1. The second buffer layer BUF2 and the third buffer layer BUF3 may include a single-layer or multi-layer inorganic insulating material.

A second semiconductor layer ACT2 may include an oxide semiconductor pattern that forms a semiconductor channel in the second TFT TFT2. A second gate insulating layer GI2 may be deposited on the third buffer layer BUF3 to cover the second semiconductor layer ACT2. The second gate insulating layer GI2 may include a single-layer or multi-layer inorganic insulating material. In addition, a light shielding pattern BSM may be formed on the second buffer layer BUF2 and overlap with the second semiconductor layer ACT2. The light shielding pattern BSM may block the incident of external light into the second semiconductor layer ACT2, which otherwise would induce unwanted charge carriers in the second semiconductor layer ACT2, which may affect the electrical characteristics of the TFT2. With less light-induced interference, the TFT2 can operate more stably and accurately. The threshold voltage of the TFT2 remains more consistent, and the on/off current ratio is improved. This leads to better control of the pixel voltages and more accurate color reproduction, as the TFT2 can precisely control the amount of current flowing to the pixels.

A second metal layer may be formed on the second gate insulating layer GI2. The second metal layer may be insulated from the second semiconductor layer by the second gate insulating layer GI2.

The second metal layer may include single-layer metal patterns or multi-layer metal patterns patterned in a photolithography process. The second metal layer may include the gate electrode GE2 of the second TFT TFT2.

The light transmitting wire SL2 may be disposed on the second interlayer insulating layer ILD2. A third interlayer insulating layer ILD3 may be disposed on the second interlayer insulating layer ILD2. The light transmitting wire SL2 may be disposed on a layer higher than the gate electrode GE2 of the second TFT TFT2.

The second interlayer insulating layer ILD2 and the third interlayer insulating layer ILD3 include a single-layer or multi-layer inorganic insulating material. A third metal layer is formed on the third interlayer insulating layer ILD3. The third metal layer is insulated from the second metal layer by the second interlayer insulating layer ILD2 and the third interlayer insulating layer ILD3.

The third metal layer includes single-layer metal patterns or multi-layer metal patterns patterned in a photolithography process. The third metal layer includes multiple first electrodes SD1.

The first electrode SD1 of the first TFT TFT1 may be electrically connected to the first semiconductor layer ACT1 through a first contact CH1 penetrating the insulating layers GI1, ILD1, BUF2, GI2, ILD2, ILD3. The first electrode SD1 of the first TFT TFT1 may be electrically connected to the light transmitting wire SL2 through a third contact CH3.

The first electrode SD1 of the second TFT TFT2 is connected to the second semiconductor layer ACT2 through a contact hole penetrating the insulating layers GI2, ILD2, ILD3.

The first planarization layer PLN1 covers the patterns of the third metal layer. The first planarization layer PLN1 may thickly cover the display area with an organic insulating material.

A fourth metal layer is formed on the first planarization layer PLN1. The fourth metal layer is insulated from the third metal layer by the first planarization layer PLN1. The fourth metal layer includes single-layer metal patterns or multi-layer metal patterns patterned in a photolithography process. The fourth metal layer may form a metal wire SL1 connected to the first electrode of the light-emitting element. The metal wire SL1 is connected to the first electrode SD1 of the first TFT TFT1 through the second contact CH2 penetrating the first planarization layer PLN1.

A second planarization layer PLN2 may be formed on the first planarization layer PLN1 to cover the metal patterns of the fourth metal layer. The second planarization layer PLN2 thickly covers the display area with an organic insulating material. A fifth metal layer is formed on the second planarization layer PLN2. The second planarization layer PLN2 planarizes the surface on which the fifth metal layer is formed.

The fifth metal layer includes single-layer metal patterns or multi-layer metal patterns patterned in a photolithography process. The pattern of the fifth metal layer includes the anode electrode AND of the light-emitting element. The anode electrode AND contacts the metal wire SL1 connected to the first TFT TFT1 through a contact hole penetrating the second planarization layer PLN2.

A bank BNK is formed on the second planarization layer PLN2 to cover the edge of the anode electrode AND. Here, the bank BNK is formed as a pattern that defines the light-emitting region (or aperture region) for each pixel. Accordingly, the bank BNK may be referred to as a pixel defining film. The bank BNK includes a photosensitive organic insulating material and may be patterned in a photolithography process. And, a spacer SPC of a certain height may be formed on the bank BNK. Here, the bank BNK and the spacer SPC may be integrally formed with the same organic insulating material. And the spacer SPC secures the gap between the FMM (Fine Metal Mask) and the anode electrode AND to prevent or obviate the FMM from contacting the anode electrode during the deposition process of the light-emitting element which is formed of organic compound.

A seventh metal layer used as the cathode electrode CAT of the light-emitting element is formed on the bank BNK and an organic compound layer EL. The seventh metal layer is connected between the sub-pixels in the display area DA. Here, the organic compound layer EL may be referred to as an emitting layer or an electroluminescent layer. The encapsulation layer 16 includes a multi-layer insulating layer covering the cathode electrode CAT of the light-emitting element.

Referring to FIG. 11, the light transmitting wire SL2 may be composed of the same material as the second semiconductor layer ACT2 of the second transistor TFT2, instead of ITO. When forming the second semiconductor layer ACT2, the light transmitting wire SL2 may be formed together using a mask pattern. Therefore, the light transmitting wire SL2 may be disposed in the same layer as the second semiconductor layer ACT2. If the second semiconductor layer ACT2 is composed of IGZO, the light transmitting wire SL2 may also be composed of IGZO.

The resistance of the IGZO may be lowered in the process of becoming conductive. Additionally, when the light transmitting wire SL2 is formed of IGZO, the width of the light transmitting wire SL2 may be increased to reduce the resistance. Therefore, the width of the light transmitting wire SL2 may be wider than the width of the metal wire SL1.

The thickness of the light transmitting wire SL2 may be different from the thickness of the second semiconductor layer ACT2, but the embodiments of this specification are not limited thereto. For example, the light transmitting wire SL2 and the second semiconductor layer ACT2 may be formed at the same time so that they may have the same thickness. For example, the thickness of the light transmitting wire SL2 may be thinner than the second semiconductor layer ACT2. Making the thickness of the light transmitting wire SL2 thinner than the second semiconductor layer ACT2 may increase the light transmittance.

The cathode electrode CAT may include an opening hole removed in the portion corresponding to the light transmitting area TA to increase the transmittance. The portion of the cathode electrode CAT corresponding to the light transmitting area TA may be patterned to be floated and then electrically connected to the light transmitting wire SL2. Therefore, the area of the wire may increase, resulting in a reduction of the resistance.

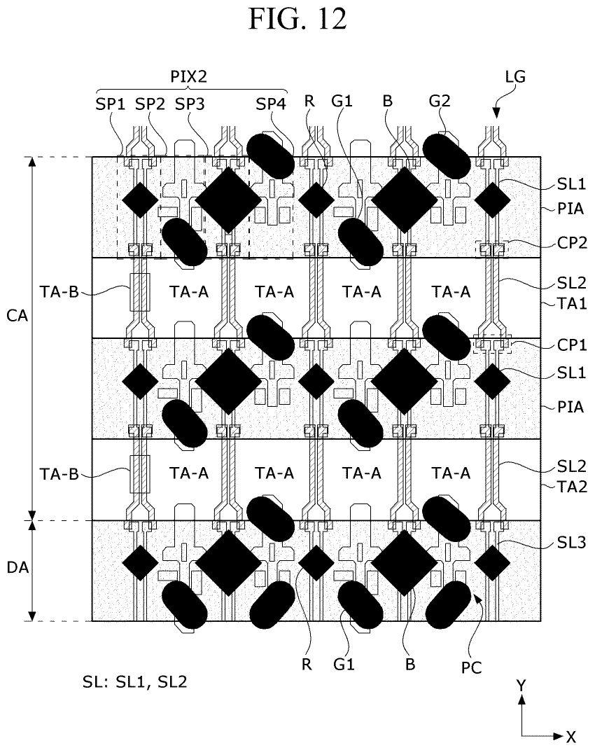

FIG. 12 is a diagram showing the sub-pixels and the light transmitting areas of the second display area according to an embodiment of the disclosure.

Referring to FIG. 12, the pixel area PIA may include multiple sub-pixels SP1, SP2, SP3, SP4. The multiple sub-pixels SP1, SP2, SP3, SP4 may constitute one second pixel PIX2, including a red sub-pixel SP1, a first green sub-pixel SP2, a blue sub-pixel SP3, and a second green sub-pixel SP4.

The red sub-pixel SP1 may include a red light-emitting element, the first green sub-pixel SP2 and the second green sub-pixel SP4 may each include a green light-emitting element, and the blue sub-pixel SP3 may include a blue light-emitting element. The red light-emitting element and the green light-emitting element may be arranged not to overlap the connection portions CP1, CP2 where the light transmitting wire SL2 and the metal wire SL1 are connected. The blue light-emitting element may be arranged not to overlap the connection portions CP1, CP2, but may partially overlap the connection portions CP1, CP2 depending on the size of the blue light-emitting element.

The first display area DA may be disposed adjacent to the edge of the second display area CA. The metal wire SL3 of the first display area DA does not have a structure connected to the light transmitting wire, but may extend continuously in the second direction to apply a driving voltage to each pixel. The second display area CA may have a lower pixel density than the first display area DA. The pixel area PIA of the second display area CA may have higher transmittance than the pixel area of the first display area DA.

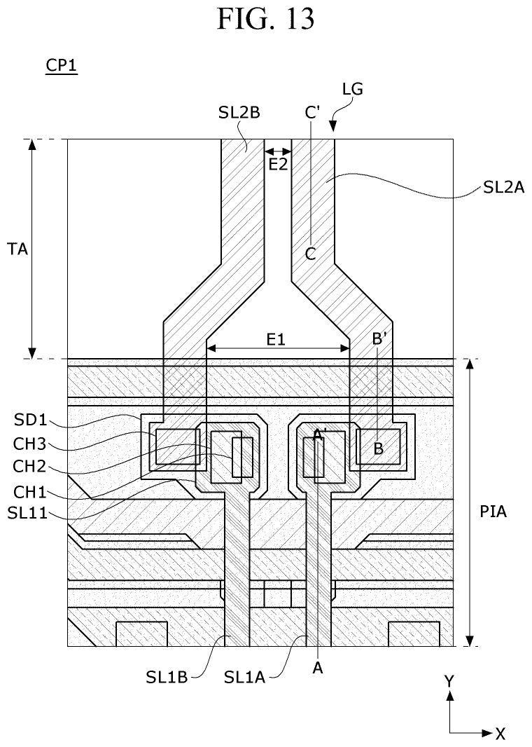

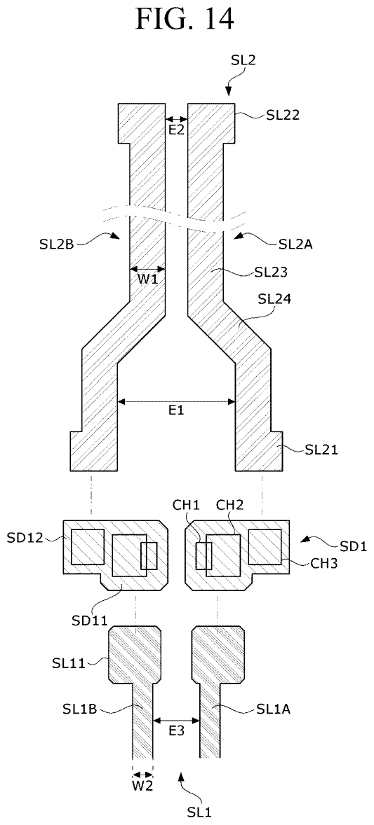

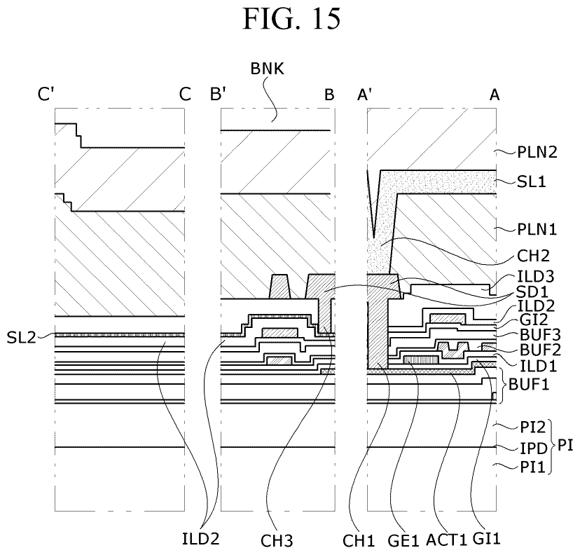

FIG. 13 is a partially enlarged view of the first connection portion of FIG. 12. FIG. 14 is an exploded view of the wire of FIG. 13. FIG. 15 is a cross-sectional view in the A-A′, B-B′, and C-C′ directions of FIG. 13.

Referring to FIGS. 13 to 15, the first light transmitting wire SL2A and the second light transmitting wire SL2B constituting a pair of wire groups LG may be electrically connected to the first metal wire SL1A and the second metal wire SL1B through the first electrode SD1.

The width W1 of the light transmitting wire SL2 may be wider than the width W2 of the metal wire SL1. The metal wire SL1 has relatively lower resistance than the light transmitting wire SL2 such as ITO, so the width W1 of the light transmitting wire SL2 may be designed to be larger than the width W2 of the metal wire SL1 to reduce the resistance in the light transmitting area TA.

The first electrode SD1 may include a first contact area SD11 where the first contact CH1 connected to the semiconductor layers of the transistor and the second contact CH2 electrically connected to the metal wire SL1 are disposed, and a second contact area SD12 where the third contact CH3 connected to the end of the light transmitting wire SL2 is disposed.

The first interval E1 between the first ends SL21 of the first light transmitting wire SL2A and the second light transmitting wire SL2B may be wider than the second interval E2 between the second ends SL22 of the first light transmitting wire SL2A and the second light transmitting wire SL2B. The third interval E3 between the first metal wire SL1A and the second metal wire SL1B may be narrower than the first interval E1 and wider than the second interval E2.

The first light transmitting wire SL2A and the second light transmitting wire SL2B may include an extension portion SL23 maintaining a constant interval, and a bent portion SL24 where the interval gradually widens towards the first end SL21. Therefore, the first contact CH1 connecting the first electrode SD1 and the semiconductor layers of the transistor and the third contact CH3 connecting the first electrode SD1 and the light transmitting wire SL2 may be arranged so that they are offset and do not overlap on the plane. By forming the first contact CH1 and the third contact CH3 not to overlap, the first electrode SD1 may be connected to the semiconductor layers of the transistor and the light transmitting wire SL2, respectively. If the first contact CH1 and the third contact CH3 overlap, the first contact CH1 is required to penetrate the light transmitting wire SL2, making it difficult to contact the semiconductor layers of the transistor.

According to the embodiment, the first contact CH1 and the second contact CH2 may also be overlapped on the plane. The second contact CH2 may be disposed on the upper part of the first contact CH1.

The first contact CH1 of the first electrode SD1 may be electrically connected to the first semiconductor layer ACT1 by penetrating the insulating layers GI1, ILD1, BUF2, BUF3, GI2, ILD2, ILD3. The third contact CH3 of the first electrode SD1 may be electrically connected to the light transmitting wire SL2 by penetrating the third interlayer insulating layer ILD3.

The metal wire SL1 includes a second contact CH2 electrically connected to the first electrode SD1 by penetrating the first planarization layer PLN1, and the third contact CH3 may be overlapped on the plane with the second contact CH2.

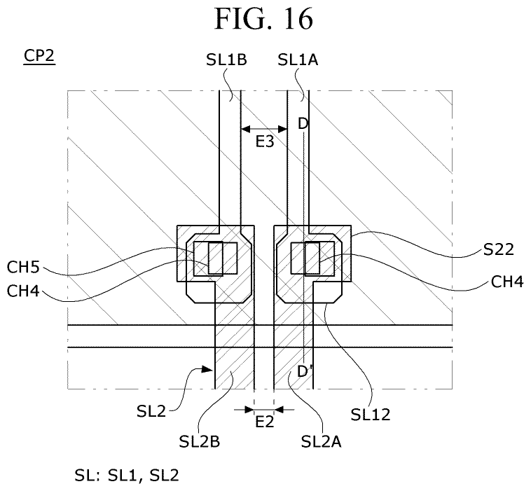

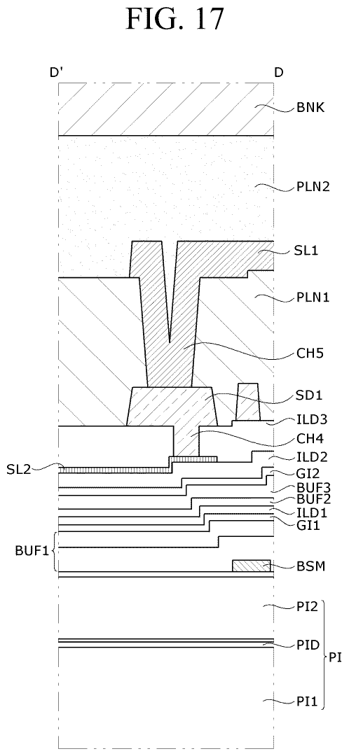

FIG. 16 is a partially enlarged view of the second connection portion. FIG. 17 is a cross-sectional view in the D-D′ direction of FIG. 16.

Referring to FIGS. 16 and 17, in the second connection portion CP2, the second end (SL12) of the metal wire SL1 and the second end SL22 of the light transmitting wire SL2 may be connected. The second end SL12 of the first metal wire SL1A may be connected to the second end SL22 of the first light transmitting wire SL2A, and the second end SL12 of the second metal wire SL1B may be connected to the second end SL22 of the second light transmitting wire SL2B.

The first electrode SD1 may be disposed between the second end SL12 of the metal wire SL1 and the second end SL22 of the light transmitting wire SL2. The first electrode SD1 may be electrically connected to the light transmitting wire SL2 through the fourth contact CH4. The metal wire SL1 may be electrically connected to the first electrode SD1 through the fifth contact CH5.

The fourth contact CH4 of the first electrode SD1 may be electrically connected to the light transmitting wire SL2 by penetrating the third interlayer insulating layer (ILD3). The fifth contact CH5 of the metal wire SL1 may be electrically connected to the first electrode SD1 by penetrating the first planarization layer PLN1. The fifth contact CH5 may be overlapped on the plane with the fourth contact CH4.

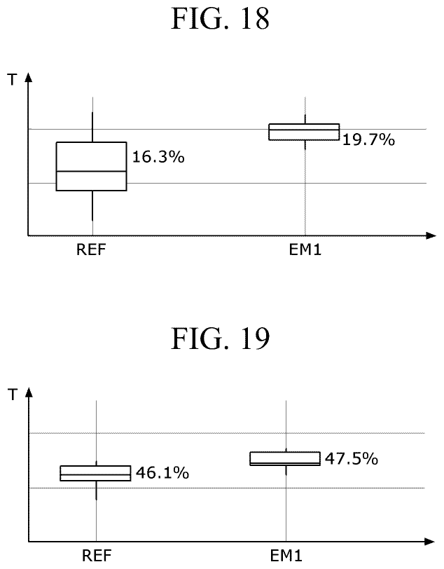

FIG. 18 shows the result of measuring the transmittance of the display device according to the embodiment of the disclosure. FIG. 19 shows the result of measuring the zero-order resonance (ZOR) characteristics of the display device according to the embodiment of the disclosure.

Referring to FIG. 18, in the case of a display device REF that placed a metal-based wire in the light transmitting area TA of the second display area CA, the transmittance of light with a wavelength of 940 nm was 16.3%, while in the case of a display device EM1 that placed a light transmitting wire SL2 in the light transmitting area TA of the second display area CA, the transmittance of light with a wavelength of 940 nm was improved by 3.4% to 19.7%. Therefore, it can be confirmed that the amount of infrared light that can be received by the infrared camera has increased, improving the performance. In the drawing, the Y-axis represents the transmittance T.

Referring to FIG. 19, in the case of a display device REF that placed a metal-based wire in the light transmitting area TA of the second display area CA, the zero-order resonance (ZOR) characteristic at a wavelength of 940 nm was 46.1%, while in the case of a display device EM1 that placed a light transmitting wire SL2 in the light transmitting area TA of the second display area CA, the zero-order resonance (ZOR) characteristic at a wavelength of 940 nm was improved by 1.4% to 47.5%. As the zero-order resonance characteristic increases, it may be more favorable to generate a 3D image feature map using infrared light.

Since the content of the specification describing the problem to be solved, means for solving the problem, and effects does not specifically define essential features of the appended claims, the scope of rights of the appended claims is not limited by the content described in the specification.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### EXPLANATION OF REFERENCE NUMERALS

DA: First Display Area
CP1: First connection portion
PIA: Pixel Area
SL2: Light transmitting Wire
CA: Second Display Area
CP2: Second connection portion
SL1: Metal Wire

What is claimed is:

1. A display device comprising:
a first display area including a plurality of first pixels; and
a second display area including a plurality of pixel areas where a plurality of second pixels are arranged and a plurality of light transmitting areas arranged between the plurality of pixel areas,
wherein the second display area includes:
a plurality of metal wires arranged in the plurality of pixel areas, and
a plurality of light transmitting wires arranged in the plurality of light transmitting areas and connected to the plurality of metal wires respectively.

2. The display device of claim 1, wherein:
the metal wires in the pixel areas are spaced apart with the light transmitting areas interposed therebetween, and
the plurality of light transmitting wires extend into the pixel areas to connect the adjacent metal wires.

3. The display device of claim 1, wherein the plurality of light transmitting wires form wire groups, each of which having two or more light transmitting wires, and the plurality of wire groups are spaced apart from each other.

4. The display device of claim 3, wherein the light transmitting wires in each of the wire groups include a first end and a second end, and an interval between the light transmitting wires becomes wider towards the first end.

5. The display device of claim 4, wherein a first interval between the light transmitting wires at the first end is wider than a second interval between the metal wires corresponding to the light transmitting wires, and the second interval is wider than a third interval between the light transmitting wires at the second end.

6. The display device of claim 1, wherein the second display area includes a first connection portion where one end of a metal wire is electrically connected to a corresponding light transmitting wire, and a second connection portion where the other end of the metal wire is electrically connected to the corresponding light transmitting wire, and
wherein both the first connection portion and the second connection portion are disposed within the plurality of pixel areas.

7. The display device of claim 1, wherein each of the plurality of first pixels and the plurality of second pixels includes a light-emitting element including an anode electrode, an emitting layer and a cathode electrode, and
wherein the cathode electrode extends across the first display area and the second display area, and includes an opening hole removed in a portion corresponding to the light transmitting area.

8. The display device of claim 7, wherein the portion of the cathode electrode corresponding to the light transmitting areas is patterned to be floated and electrically connected to the light transmitting area.

9. The display device of claim 1, wherein:
the pixel area includes a first electrode connecting an end of the metal wire and an end of the light transmitting wire, and
the first electrode includes a first contact connected to a semiconductor layer of a transistor and a third contact connected to the light transmitting wire.

10. The display device of claim 9, wherein the first contact and the third contact are spaced apart from each other and do not overlap on a plane.

11. The display device of claim 9, wherein the metal wire includes a second contact connected to the first electrode.

12. The display device of claim 11, wherein the first contact and the second contact overlap on a plane.

13. The display device of claim 1, wherein a width of the light transmitting wire is wider than a width of the metal wire.

14. The display device of claim 1, wherein the light transmitting wire is disposed in a same layer as a semiconductor layer of a transistor.

15. The display device of claim 1, wherein the second display area includes:
a substrate;
a first semiconductor layer disposed on the substrate;
a first gate insulating layer disposed on the first semiconductor layer;
the light transmitting wire disposed over the first gate insulating layer;
an insulating layer disposed on the light transmitting wire;
a first electrode disposed on the insulating layer;
a first planarization layer disposed on the first electrode; and
a metal wire disposed on the first planarization layer.

16. The display device of claim 15, further comprising:
a second semiconductor layer disposed on the first gate insulating layer, and
a second gate insulating layer disposed on the second semiconductor layer,
wherein the light transmitting wire is disposed over the second gate insulating layer.

17. The display device of claim 15, wherein the first electrode includes a first contact connected to the first semiconductor layer through the first gate insulating layer and the insulating layer, and a second contact electrically connected to the light transmitting wire through the insulating layer.

18. The display device of claim 17, wherein the first contact and the second contact are offset on a plane.

19. The display device of claim 17, wherein the metal wires include a third contact electrically connected to the first electrode through the first planarization layer.

20. A display device, comprising:
a first display area including a plurality of first pixels; and
a second display area including a plurality of pixel areas where a plurality of second pixels are arranged and a plurality of light transmitting areas arranged between the plurality of pixel areas,
wherein a plurality of signal wires extends within the second display area to pass through the plurality of pixel areas and the plurality of light transmitting areas,
wherein each of the plurality of signal wires includes a metal wire disposed in the pixel areas and a light transmitting wire disposed in the light transmitting areas and electrically connected to the metal wire.
